(19) United States
(12) Patent Application Publication
(10) Pub. No.: US 2007/0069295 A1
(43) Pub. Date: Mar. 29, 2007

(54) Process to integrate fabrication of bipolar devices into a CMOS process flow

(76) Inventors: Daniel Charles Kerr, Orlando, FL (US); Mamata Patnaik, Windermere, FL (US); Mario Pita, Harmony, FL (US); Venkat Raghavan, Union City, CA (US); Alan Sangone Chen, Windermere, FL (US)

Correspondence Address: MENDELSOHN & ASSOCIATES, P.C., 1500 JOHN F. KENNEDY BLVD., SUITE 405, PHILADELPHIA, PA, 19102, US

(21) Appl. No.: 11/237,634

(22) Filed: Sep. 28, 2005

(51) Int. Cl. H01L 21/8238; H01L 21/8249; H01L 27/12

(52) U.S. Cl. 257/351; 438/202; 438/234; 257/E21.269

(57) ABSTRACT

A BiCMOS method for forming bipolar junction transistors and CMOS devices in a substrate. To avoid erosion of the bipolar junction transistor material layers, gate spacers for the CMOS devices are formed while a bipolar junction transistor photoresist layer is in place. The photoresist layer is used for etching the emitter polysilicon layer (for single polysilicon layer bipolar junction transistors) or for etching the base polysilicon layer (for double polysilicon layer bipolar junction transistors) prior to gate spacer etch.

### FIELD OF THE INVENTION

This invention relates generally to fabrication of complementary metal oxide semiconductor field effect transistor devices (CMOS), and more specifically, to fabrication of bipolar junction transistor devices (BJT) into a CMOS fabrication process flow.

### BACKGROUND OF THE INVENTION

Integrated circuits typically comprise semiconductor devices, such as bipolar junction transistors (BJTS) and metal-oxide semiconductor field effect transistors (MOSFETS) formed in doped regions within a semiconductor layer. Overlying levels of interconnect, formed in dielectric layers, electrically connect the doped regions to form circuits. Conductive vias, also disposed in the dielectric layers, connect conductive runners or traces in different levels.

BiCMOS integrated circuits comprise both bipolar junction transistors and CMOS (complementary metal oxide semiconductor field effect) transistors with the fabrication process steps of all devices integrated into one fabrication sequence.

During the first several steps of one typical prior art BiCMOS fabrication sequence, certain of the CMOS features are first fabricated. These initial CMOS steps may include: forming isolation regions in a semiconductor layer to electrically isolate subsequently-formed CMOS transistors, implanting dopants to form n-type and p-type tubs in which p-channel and n-channel MOSFETS are later formed, depositing and etching material layers of MOSFET gate structures, implanting lightly doped drain regions in the n-type and p-type tubs and depositing material layers from which gate spacers are subsequently formed.

Next processing may switch to the bipolar transistor fabrication. For a bipolar junction transistor having a single polysilicon layer from which the emitter is formed (referred to as an implanted base process), the process steps may include: implanting dopants to form the collector and the base regions, depositing and patterning material layers to form an emitter window, depositing and doping the emitter polysilicon layer within the emitter window, depositing a photoresist layer to mask the emitter polysilicon layer, etching the polysilicon layer to form the emitter and stripping off the emitter photoresist.

Subsequently, further fabrication of the CMOS devices includes: etching to form gate spacers and implanting of dopants in the n-type and p-type wells to form source and drain regions for each MOSFET. At this point, fabrication of the CMOS and bipolar junction transistor devices is substantially complete.

For a bipolar junction transistor having a double polysilicon layer (wherein an extrinsic base is formed from a first polysilicon layer and an emitter is formed from a second polysilicon layer) formation of the bipolar junction transistors follows the same initial CMOS steps as set forth above in conjunction with fabrication of the single polysilicon layer bipolar junction transistor. The double-polysilicon layer bipolar junction transistor advantageously exhibits lower base resistance and lower collector-base capacitance than the single-polysilicon layer bipolar junction transistor.

Following the initial CMOS steps, processing may switch to the double polysilicon-layer bipolar transistor fabrication and may include: implanting dopants to form the collector, depositing a base polysilicon layer (for forming the extrinsic base) and a base silicon-nitride layer, forming an emitter window in the base polysilicon and silicon-nitride layer, depositing and etching a silicon nitride layer to form first silicon nitride spacers on the emitter window sidewalls (to prevent epitaxial silicon growth on the sidewalls during a next epitaxial growth step), forming an intrinsic base by epitaxial growth in a portion of the emitter window, forming second silicon nitride spacers within the emitter window, forming an emitter polysilicon layer over the substrate and within the emitter window, patterning the emitter polysilicon layer to form a bipolar junction transistor emitter and patterning the base polysilicon layer to form the extrinsic base. Processing then returns to fabrication of the remaining CMOS device features as described above in conjunction with fabrication of the single-polysilicon layer bipolar junction transistor.

After formation of the various bipolar junction transistor and MOSFET regions in the semiconductor layer, an interconnect system is formed from alternating dielectric and conductive material layers overlying the semiconductor layer. A first dielectric layer is deposited over the semiconductor layer, openings are formed in the first dielectric layer and conductive material deposited therein to form conductive vias in electrical contact with the doped regions within the semiconductor layer. A first conductive layer is deposited over the dielectric layer and patterned to form horizontal conductive regions that connect the conductive vias. Additional dielectric layers and conductive interconnect layers are alternately formed over the first conductive layer to complete fabrication of the interconnect system. As is known by those skilled in the art, interconnect structures can also be formed according to a damascene process comprising substantially vertical conductive vias connected to substantially horizontal conductive runners.

Erosion of exposed surface layers of the bipolar junction transistor structure during etching to form the MOSFET gate spacers is a known disadvantage of the above-described approach for integrating the bipolar junction transistor and CMOS process flows. Depending on the bipolar junction transistor structure, the eroded upper surface layers may include a polysilicon base layer and/or a polysilicon emitter layer (i.e., depending on whether the bipolar junction transistor comprises a single or double polysilicon layer). The erosion thins these polysilicon layers, increasing layer resistance (i.e., increasing resistance of the base and/or the emitter regions) and degrading uniformity of the bipolar junction transistor upper surface. In an extreme case, the bipolar junction transistor can be rendered nonfunctional by excessive layer erosion.

Known techniques to limit layer erosion include forming thicker polysilicon layers for the base and/or the emitter, such that after erosion the layers are sufficiently thick and exhibit a sufficiently low resistance. However, this technique increases the stack height of the bipolar junction transistor material layers. Also, etching of the thicker polysilicon layers, to form the required structural shapes for the base and/or the emitter is more difficult. Properly filling an emitter window in the base polysilicon layer (for forming the emitter region) is more difficult as the thickness of the base polysilicon layer increases.

According to another known prior art technique, bipolar junction transistor surface layer erosion is limited by careful control of the MOSFET gate spacer etch process, but this technique adds cost to the fabrication process.

In certain process technologies it is desirable to form precision resistors in the polysilicon layer used to form the emitter. Since the final thickness of the polysilicon layer cannot be fully controlled, due to erosion during gate spacer etch, the resistance of these polysilicon resistors may not be within a specified tolerance. To avoid this problem, precision resistors are simply not formed in the emitter polysilicon layer, restricting the diversity of circuits that can be incorporated into the integrated circuit.

### BRIEF SUMMARY OF THE INVENTION

According to one embodiment, the present invention comprise a method for forming a bipolar junction transistor and a metal oxide semiconductor field effect transistor in a semiconductor layer. The method comprises providing the semiconductor layer, forming MOSFET structures in a MOSFET region of the semiconductor layer, depositing a spacer material layer over an upper surface of the semiconductor layer, forming bipolar junction transistor structures, including an emitter material layer, in a bipolar junction transistor region of the semiconductor layer, forming a patterned mask, etching the emitter material layer using the mask to form an emitter, etching the spacer material layer to form gate stack spacers in the MOSFET region prior to removing the mask and removing the mask.

The present invention also comprises semiconductor structures comprising bipolar junction transistor structures and metal oxide semiconductor field effect transistor structures in a semiconductor layer. The semiconductor structures comprise a collector in a bipolar junction transistor region of the semiconductor layer, a base in contact with the collector, an emitter overlying an upper surface of the semiconductor layer, a patterned mask overlying the emitter, MOSFET structures, including a gate stack, in a MOSFET region of the semiconductor layer and a spacer material layer overlying the gate stack wherein the spacer material layer is etched to form gate stack spacers while the patterned mask overlies the emitter.

### BRIEF DESCRIPTION OF THE DRAWING

The present invention can be more easily understood and the advantages and uses thereof more readily apparent when the following detailed description of the present invention is read in conjunction with the figures wherein:

FIGS. 1-9 are cross-sectional views taken along a common plane illustrating sequential processing steps of a BiCMOS process for forming single polysilicon layer bipolar junction transistors and CMOS devices according to a first method of the present invention.

FIGS. 10-21 are cross-sectional views taken along a common plane illustrating sequential processing steps of a BiCMOS process for forming double polysilicon layer bipolar junction transistors and CMOS devices according to a second method of the present invention.

In accordance with common practice, the various described device features are not drawn to scale, but are drawn to emphasize specific features relevant to the invention. Reference characters denote like elements throughout the figures and text.

### DETAILED DESCRIPTION OF THE INVENTION

Before describing in detail the particular method and apparatus for forming bipolar junction transistors and CMOS devices on a semiconductor substrate according to a BiCMOS process flow, it should be observed that the present invention resides primarily in a novel and non-obvious combination of elements and process steps. So as not to obscure the disclosure with details that will be readily apparent to those skilled in the art, certain conventional elements and steps have been presented with lesser detail, while the drawings and the specification describe in greater detail other elements and steps pertinent to understanding the invention. The illustrated process steps are exemplary, as one skilled in the art recognizes that certain independent steps illustrated below may be combined and certain steps may be separated into individual sub-steps to accommodate individual process variations.

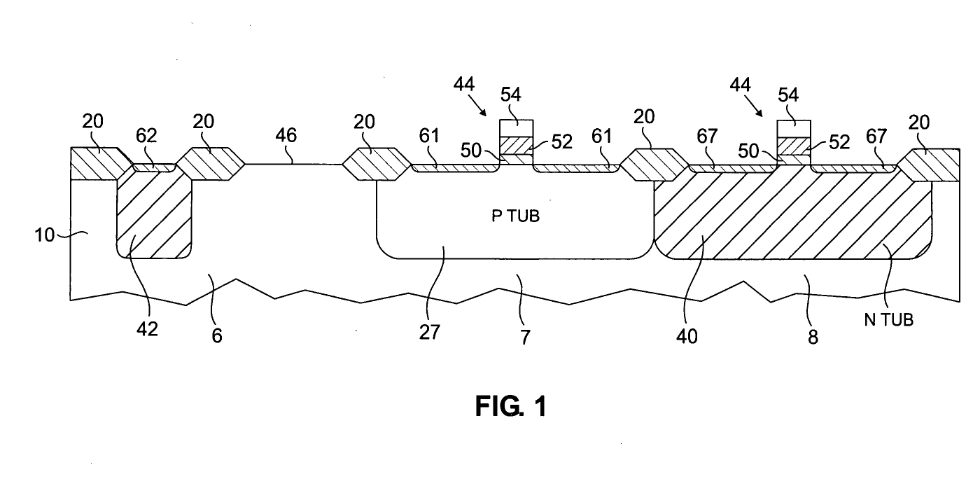

A process sequence for forming single-layer polysilicon bipolar junction transistors (also referred to as implanted base bipolar junction transistors) and MOSFETS in a BiCMOS process is described below in conjunction with FIGS. 1-9, which show cross-sectional views of formed structures according to a sequence of exemplary fabrication steps, wherein an NPN bipolar junction transistor is formed in a region 6, an NMOSFET is formed in a region 7 and a PMOSFET is formed in a region 8 of a semiconductor layer 10. See FIG. 1. The NMOSFET and the PMOSFET form a complementary MOSFET (CMOS) pair.

To avoid performance degradation and electrical cross talk between devices, it is desirable to electrically isolate bipolar junction transistors and the CMOS devices in the semiconductor layer. The exemplary process of FIG. 1 employs LOCOS (local oxidation of silicon) isolation regions 20 (see FIG. 1), but various forms of trench isolation can be used alone or in combination with the LOCOS isolation regions 20 to provide necessary device isolation. The LOCOS regions 20 are formed by first oxidizing the p-type silicon semiconductor layer 10 to form a silicon dioxide layer (not shown in FIG. 1), which is also referred to as a pad oxide layer. A silicon nitride layer (not shown in FIG. 1) is deposited overlying the silicon dioxide layer. The silicon nitride layer and an upper portion of the silicon dioxide layer are etched to form openings therein according to an overlying patterned photoresist layer. Silicon substrate regions exposed through the openings are oxidized during an oxidizing process step to form LOCOS silicon dioxide isolation regions 20 illustrated in FIG. 1. The silicon nitride and silicon dioxide layers are chemically stripped from the semiconductor layer 10 and a sacrificial screen silicon dioxide layer (not shown in FIG. 1) is formed over the semiconductor layer 10.

Next, a photoresist layer is deposited and patterned to form a mask (not shown in FIG. 1) through which a p-type dopant is implanted through to form a p-tub 27 in the NMOS region 7 of the semiconductor layer 10.

An second photoresist implant mask (not shown) is formed through which n-type dopants are implanted, forming an n-tub 40 in the PMOS region 8 and a collector sinker region 42 for an NPN bipolar junction transistor device in the region 6. The collector sinker region 42 bridges between a collector surface region and a subcollector, both of which are formed later in the process.

A wet clean process removes the second photoresist implant mask. A gate silicon dioxide layer, a polysilicon layer (doped in situ or by an implant process) and a tungsten silicide layer are blanket deposited on an upper surface 46 of the semiconductor layer 10. The tungsten silicide layer provides improved ohmic contact (reducing the sheet resistivity and the contact resistance) between the gate electrode formed from the polysilicon layer and a later-formed overlying conductive via.

A silicon dioxide layer is deposited and patterned, forming a hard mask for etching the gate silicon dioxide layer, the polysilicon layer and the tungsten silicide layer to form a gate stack 44 over each one of the p-tub 27 (in the NMOS region 7) and the n-tub 40 (in the PMOS region 8). Each gate stack 44 comprises a gate oxide region 50, a polysilicon region 52 and a tungsten silicide region 54.

Using a patterned implant mask (not shown), n-type lightly doped drain regions 61 are formed in the p-tub 27 and an n-type lightly doped collector surface region 62 is formed in the bipolar junction transistor region 6.

With another patterned implant mask (not shown), p-type lightly doped drain regions 67 are formed in the n-tub 40.

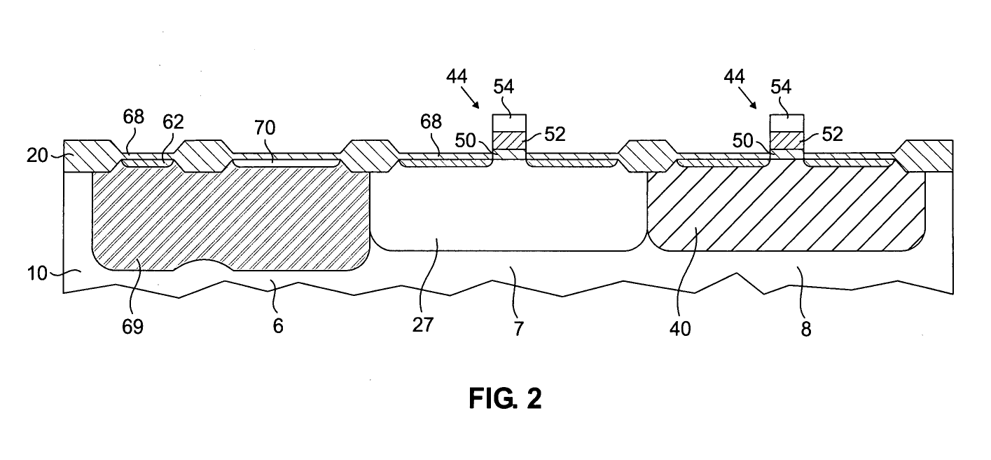

A thin TEOS (tetraethylorthosilicate) deposited silicon dioxide layer 68 (having a thickness of about 180 Angstroms in one embodiment) is formed overlying the semiconductor layer 10. See FIG. 2.

Using a subcollector mask that shields the NMOSFET region 7 and the PMOSFET region 8, a subcollector region 69 is implanted in the bipolar junction transistor region 6. To simplify the Figures, the collector sinker region 42 within the subcollector region 69 is not further illustrated. It is to be understood that the subcollector region 69 comprises several subregions, including the collector sinker region 42, a deep buried layer and a pedestal layer, each having different dopant concentrations.

Using an appropriate mask, a p-type base region 70 is formed in an upper region of the subcollector 69 by counterdoping with a p-type implant, e.g., boron.

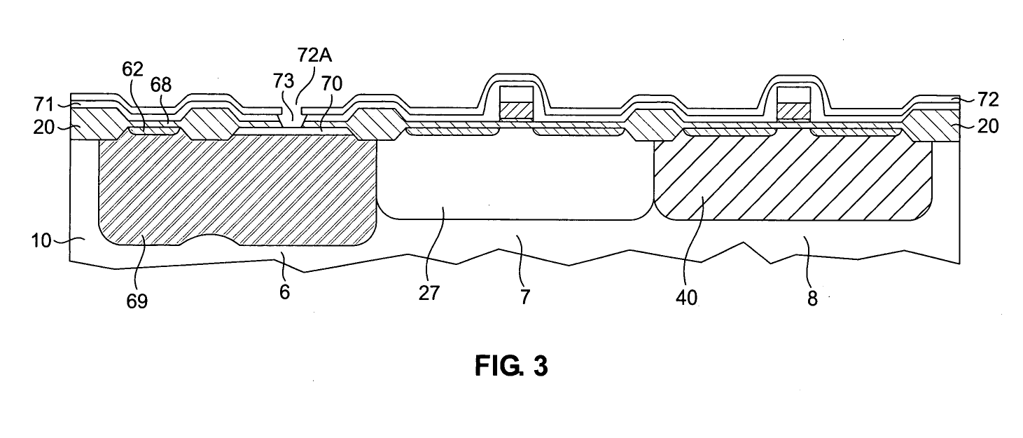

As shown in FIG. 3, a relatively thick spacer silicon oxide layer 71 is deposited over the semiconductor layer 10. In one embodiment the layer 71 is formed by a TEOS-based deposition process, resulting in a 1200 Angstrom thick oxide layer. A relatively thin silicon oxide layer 72 is deposited over the silicon oxide layer 71 and patterned to form a hard mask for a subsequent wet etch step.

A photoresist layer (not shown) is deposited and patterned to anisotropically etch an opening 72A in the hard mask silicon oxide layer 72. Then a wet etch process forms an emitter window 73 (see FIG. 3) in the silicon oxide layers 68 and 71.

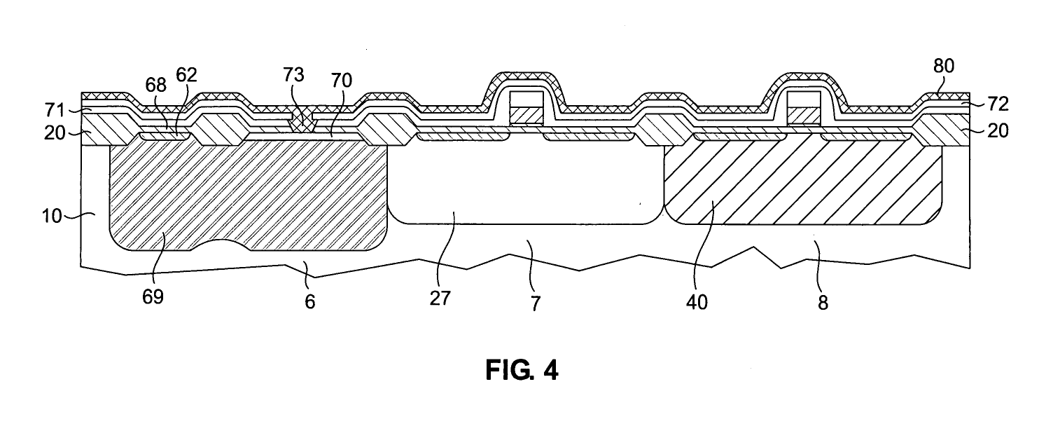

As illustrated in FIG. 4, a polysilicon layer 80 is deposited, filling the emitter window 73, forming the emitter. The polysilicon layer 80 is implanted (or doped in-situ) with arsenic or another n-type dopant.

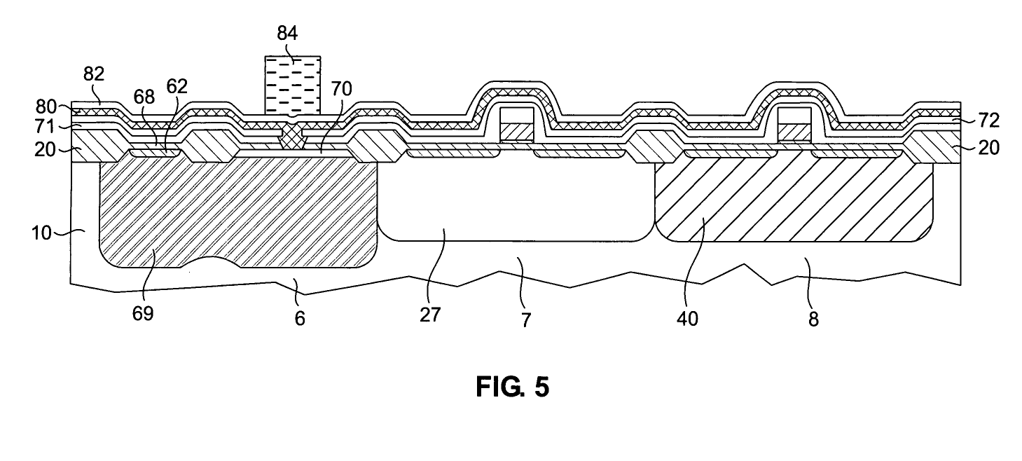

A silicon oxide layer 82 is deposited over the polysilicon layer 80 to create a hard mask for a subsequent etch step. The layer 82 is sufficiently thick to block emitter p+-type implants during a subsequent implant step. Next, a photoresist layer is deposited and patterned to form a mask 84. The resulting structure is illustrated in FIG. 5.

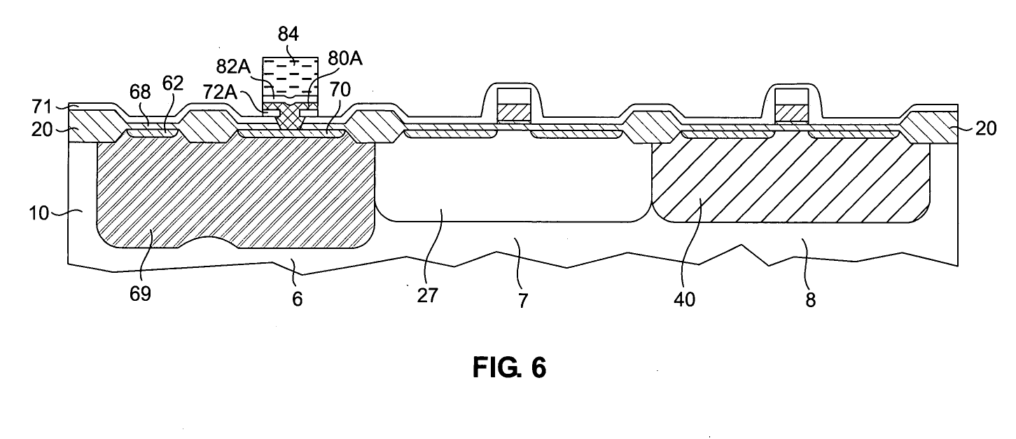

Using the photoresist mask 84, the hard mask layer 82 is then patterned to allow removal of the silicon oxide layer 82 except for a region 82A, which functions as a hard mask for removing regions of the polysilicon layer 80 and the silicon dioxide 72, defining (as illustrated in FIG. 6) a region 72A of the silicon dioxide layer 72 and an emitter region 80A (from the polysilicon layer 80).

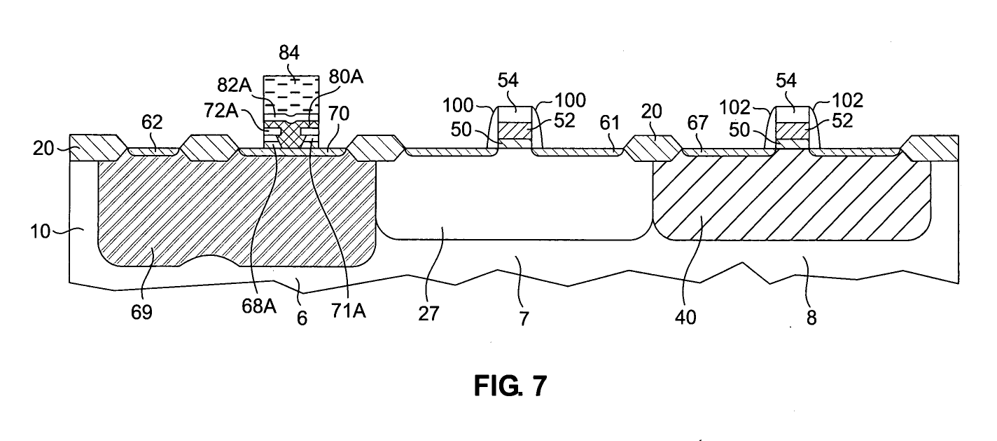

With the patterned mask 84 still in place, gate stack spacers 100 for the NMOSFET device in the region 7 and gate stack spacers 102 for the PMOSFET device in region 8 are formed by anisotropically etching the silicon dioxide layers 68 and 71. See FIG. 7. Note the material layers underlying the patterned mask 84 include the silicon oxide regions 71A and 68A formed during the gate stack spacer etch process.

An exemplary chemistry for etching the silicon dioxide layers 68 and 71 to form the gate stack spacers 100 and 102 comprises a combination of CHF3 (methyl fluoride), CF4 (carbon tetrafluoride) and Ar (argon) in an approximate ratio of 6:1:1. Approximate flow rates are at about 72 sccm CHF3, at about 12 sccm CF4 and at about 10 to about 20 sccm argon. Wafer temperature during this etching process is preferably between 30 C and 60 C. Other oxide etch chemistries can be used in lieu of the chemistry set forth above.

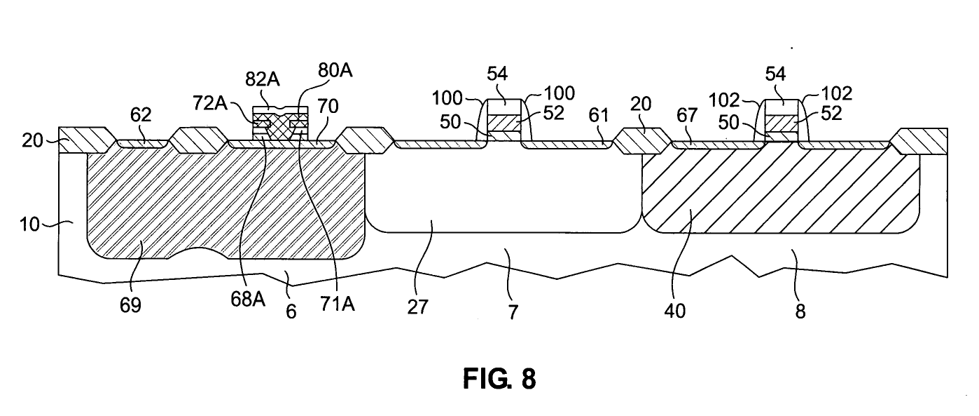

After the patterned mask 84A is removed, e.g., using a downstream oxygen-based plasma mask stripping process, the resulting structure is as illustrated in FIG. 8.

A photoresist layer (not illustrated) is next patterned to form n+source/drain regions and a collector contact by implanting arsenic into the p-tub 27 (forming a source 106 and a drain 108 for the NMOSFET in the region 7) and simultaneously implanting into the bipolar junction transistor collector region 42 (forming an n+ohmic collector contact region 110 with a relatively high doping level to minimize contact resistance with a subsequently-formed overlying collector contact).

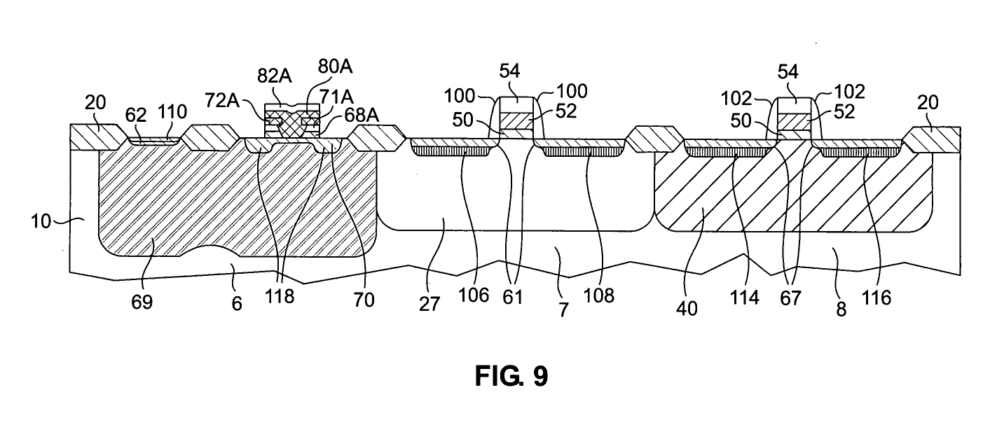

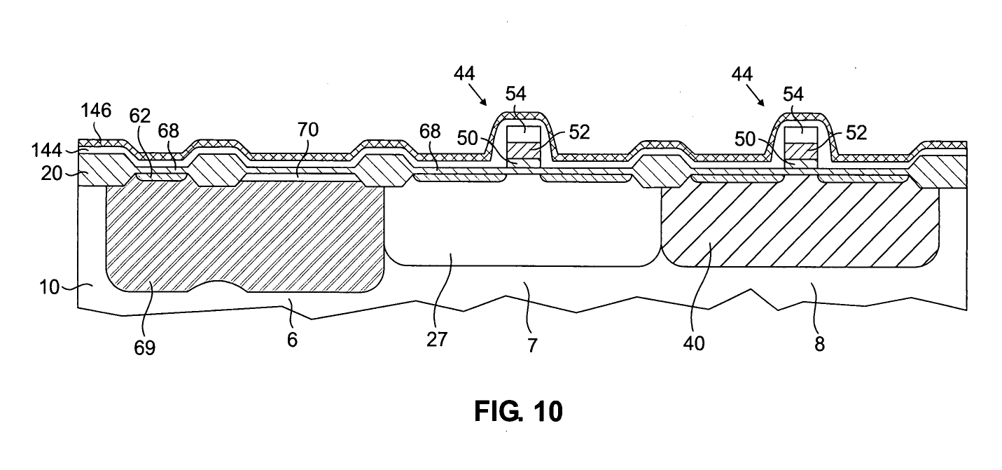

A high dose of a p-type (p+) dopant is implanted through a patterned mask (not illustrated) into the n-tub 40 to form a source 114 and a drain 116 for the PMOSFET in the region 8. Simultaneously, an extrinsic base region 118 of the NPN bipolar junction transistor is formed with the p-type dopant. FIG. 9 illustrates the final device structures prior to deposition of metallization levels, e.g., alternating dielectric and conductive layers for wiring the doped regions formed in the semiconductor layer 10.

In accordance with the invention, since the patterned mask 84 remains in place during formation of the gate stack spacers 100 and 102 there is no material erosion of the bipolar junction transistor layers within the bipolar junction transistor region 6 during the spacer etch process. Thus the sheet resistance of each bipolar junction transistor material layer is lower than the sheet resistance of these material layers when formed according to the prior art process. The lower sheet resistance reduces the material layer resistance, increasing the operational speed of the bipolar junction transistors fabricated according to the process of the present invention, compared with the bipolar junction transistors fabricated according to prior art BiCMOS processes that suffer from layer erosion during gate spacer etch.

It is known that an etch process may not uniformly etch a layer across all integrated circuits formed in the wafer (e.g., creating a center low effect). As applied to the gate spacer etch process, the etchant tends to remove all of the silicon oxide on the integrated circuit die near the wafer center before completely removing the silicon oxide on die proximate the wafer edge. Thus the etch process must be extended (referred to as over-etching) until the edge-proximate silicon dioxide has been removed. The exposed bipolar junction transistor layers of the prior art processes are especially vulnerable to erosion due to this over-etch. The present invention overcomes this disadvantage by retaining the patterned mask 84 in place until after the gate spacer etch process has been completed, avoiding erosion of the bipolar junction transistor layers and the accompanying increased layer sheet resistance.

According to a prior art BiCMOS process, a final emitter polysilicon line width measurement is made after etching the emitter polysilicon layer 80 and removing the photoresist mask 84A, but before etching the gate spacers. According to one embodiment of the present invention, the line width is measured after the polysilicon layer etch and gate spacer etch. In this case, spacer oxide formed on sidewalls of the emitter polysilicon during gate spacer etch adds to the emitter line width measurement and must subtracted from the measurement to accurately determine the emitter line width.

An exemplary double-polysilicon BiCMOS process (forming an NPN bipolar junction transistor comprising two polysilicon layers, one layer for the emitter and one layer for extrinsic base) is described below in FIGS. 1,2 and 10-21, which illustrate cross-sectional views of the formed structures according to sequential processing steps.

With the initial steps set forth in FIGS. 1 and 2 above completed a TEOS deposited spacer layer 144 and a base polysilicon layer 146 are formed on an upper surface of the semiconductor layer 10. The base polysilicon layer 146 is heavily doped with boron. Next an extrinsic base region 146 is formed from the doped base polysilicon layer 146 as described below.

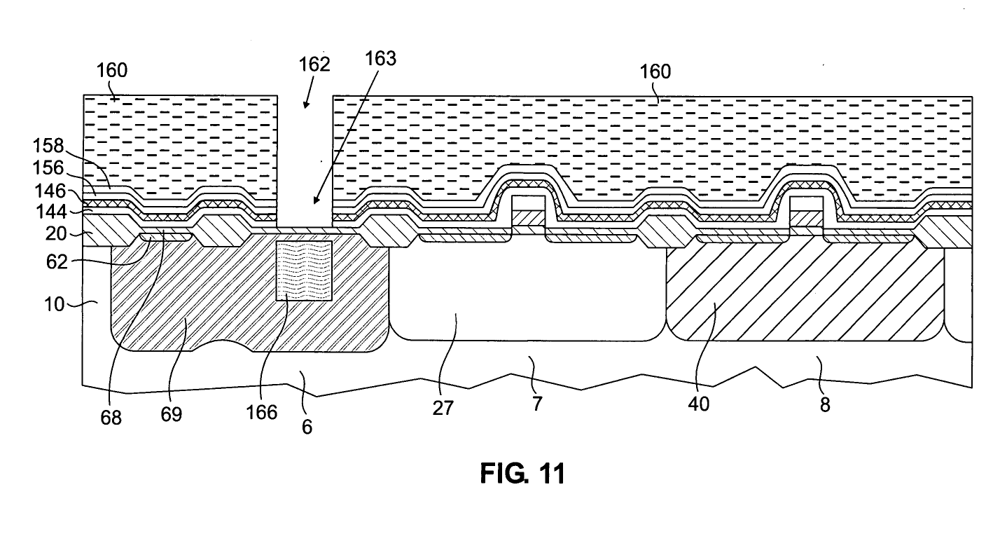

As illustrated in FIG. 11, a silicon nitride layer 156 and a silicon dioxide layer 158 (in one embodiment formed according to a TEOS-based deposition process) are deposited in a stacked relation over the base polysilicon layer 146. A patterned photoresist layer 160 defines a window 162 through which the silicon dioxide layer 158, the silicon nitride layer 156 and the base polysilicon layer 146 are anisotropically etched, stopping on the layer 144, to form an emitter window 163. In certain bipolar junction transistor embodiments an implant may be made through the window 162 to create a collector region 166.

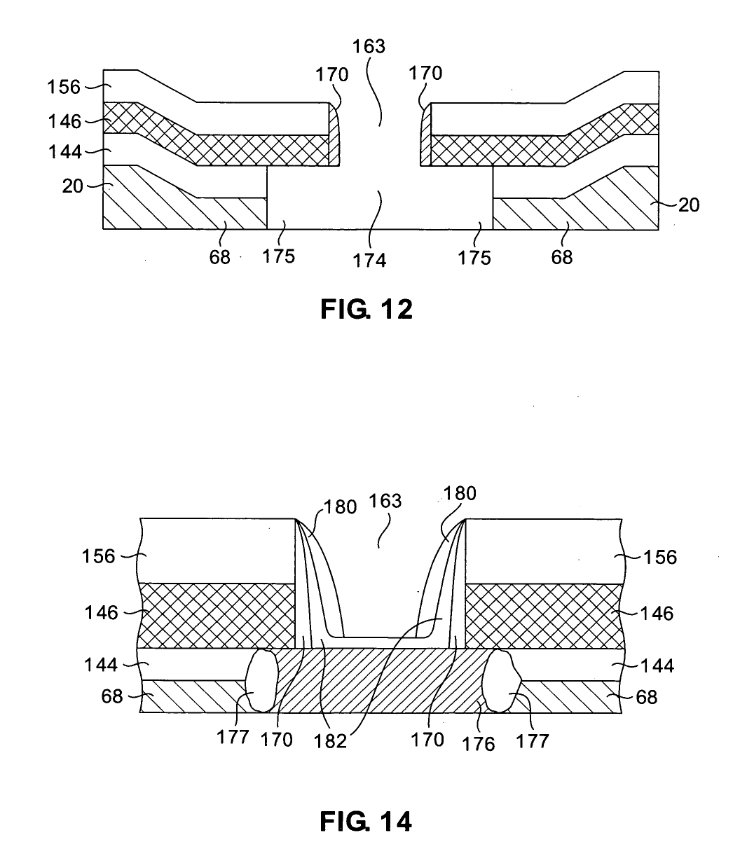

The photoresist layer 160 is removed and a layer of silicon nitride, deposited overlying the silicon dioxide layer 158, is anisotropically etched to form sidewall spacers 170. See FIG. 12. A wet etch process removes the silicon dioxide layer 158 across the semiconductor layer 10, removes the silicon dioxide layers 68 and 144 from within the emitter window 163, and forms a primary cavity 174 having laterally disposed recesses 175. The resulting structure is illustrated in FIG. 12.

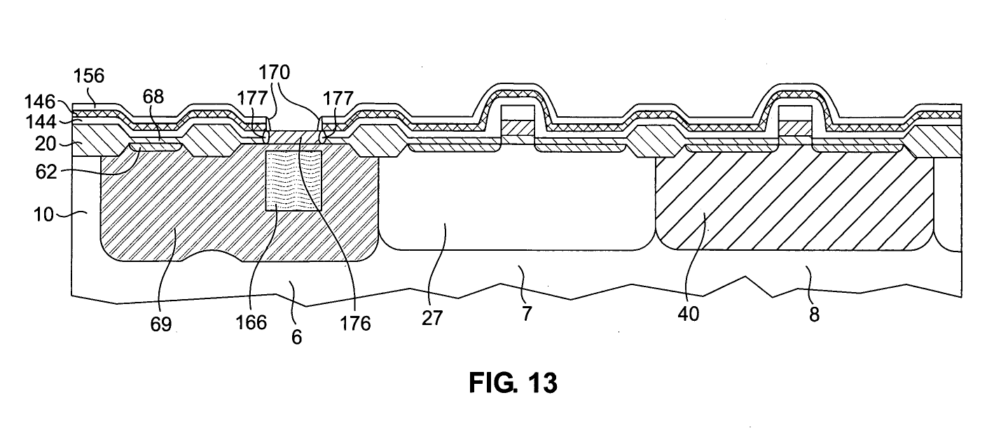

An intrinsic base and a cap region, both referred to by a reference character 176 (see FIG. 13) are formed in the cavities 174 and 175 during a silicon-germanium epitaxial growth step. Voids 177 may form in regions where the silicon-germanium does not grow.

A silicon nitride spacer 180 and an underlying TEOS-deposited silicon oxide spacer 182 are formed in the window 163 as illustrated in the close-up view of FIG. 14. The spacers, which serve to increase the space between a later-formed n+ emitter and a p+ extrinsic base, are formed by depositing a silicon oxide layer and an overlying silicon nitride layer. The layers are anisotropically etched back to form the spacers 180 and 182, with the etch stopping on a region of the silicon oxide layer 182A formed on an upper surface of the intrinsic base and cap region 176. In another embodiment the spacers 180 and 182 are not required when the previously formed spacers 170 provide sufficient isolation between the extrinsic base and the emitter.

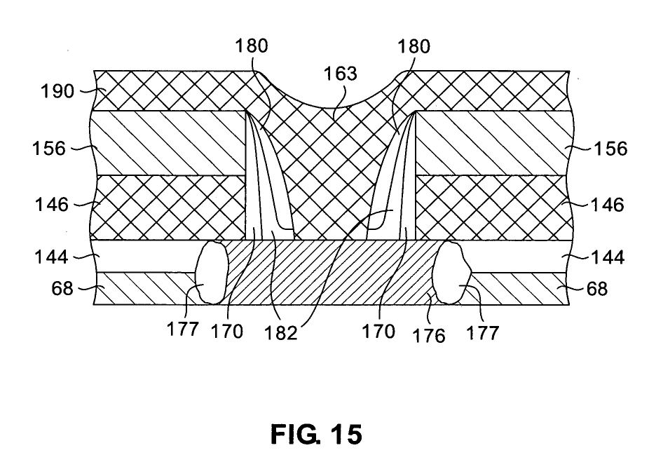

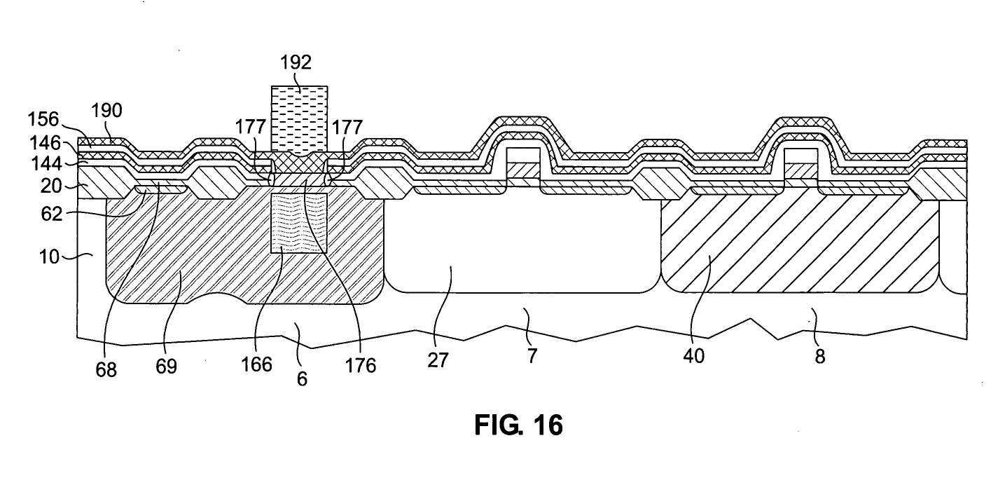

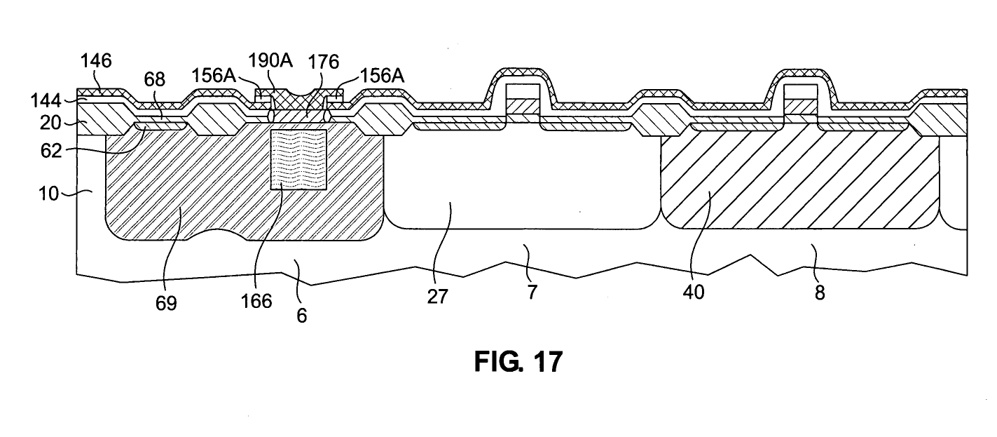

Following spacer formation, remaining portions of the TEOS silicon dioxide layer 182A overlying the upper surface of the intrinsic base and cap region 173 are removed by a wet etch process. A polysilicon layer 190 is next deposited over the semiconductor layer 10 and etched to define the bipolar junction transistor emitter. See FIGS. 15 and 16. The polysilicon layer 190 may be implanted or doped in-situ with arsenic or another n-type dopant. A photoresist layer is patterned to form a mask to etch away portions of the polysilicon layer 190 and the silicon nitride layer 156 defining a polysilicon emitter 190A and underlying silicon nitride regions 156A. The resulting structure is illustrated in FIG. 17.

According to another embodiment, a hard mask layer is deposited overlying the emitter polysilicon layer 190 and a photoresist layer is used to pattern the hard mask layer, which is then used to define the emitter polysilicon layer 190 and the silicon nitride layer 156.

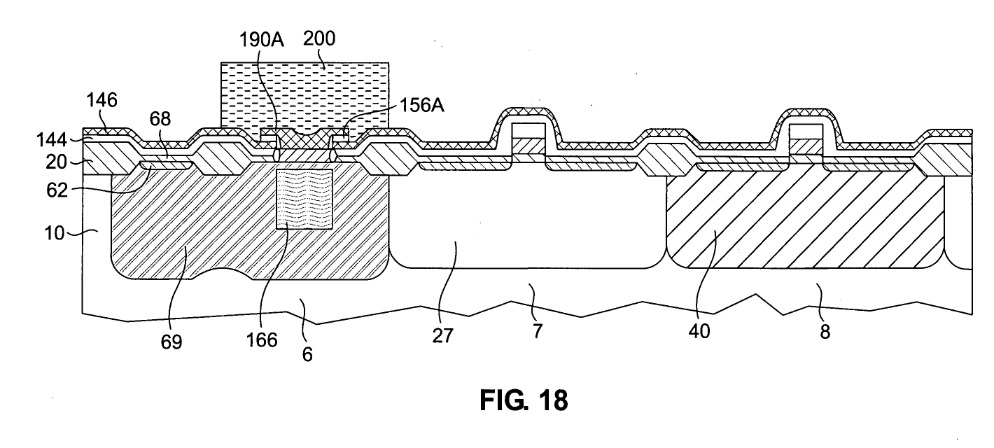

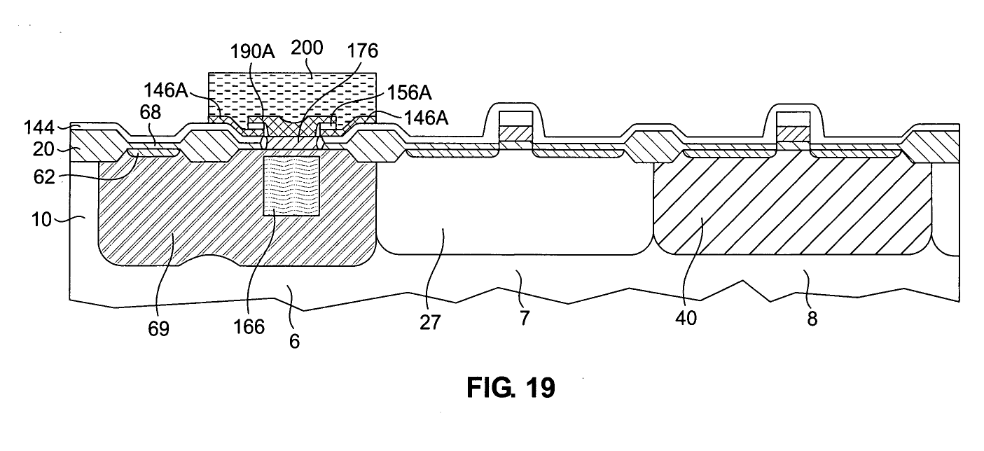

As illustrated in FIG. 18, photoresist layer is patterned to form a mask 200 to remove regions of the base polysilicon layer 146 (by etching) and form extrinsic polysilicon base regions 146A as illustrated in FIG. 19.

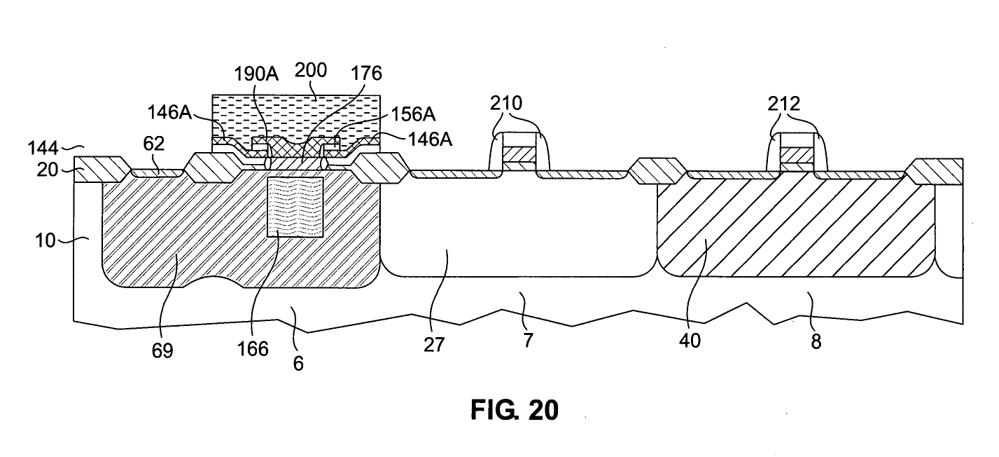

With the mask 200 still in place, gate stack spacers 210 for the NMOSFET device in the region 7 and gate stack spacers 212 for the PMOSFET device in the region 8 are formed by anisotropically etching the silicon dioxide layer 144. During this etching process, the silicon oxide layer 68 is also removed. See FIG. 20.

An exemplary etch chemistry for forming the gate stack spacers 100 and 102 comprises a combination of CHF3 (methyl fluoride), CF4 (carbon tetrafluoride) and Ar (argon) in an approximate ratio of 6:1:1. Approximate flow rates are CHF3 at about 72 sccm , CF4 at about 12 sccm and Ar at about 10-20 sccm. Wafer temperature during this etching process is preferably between 30 C and 60 C.

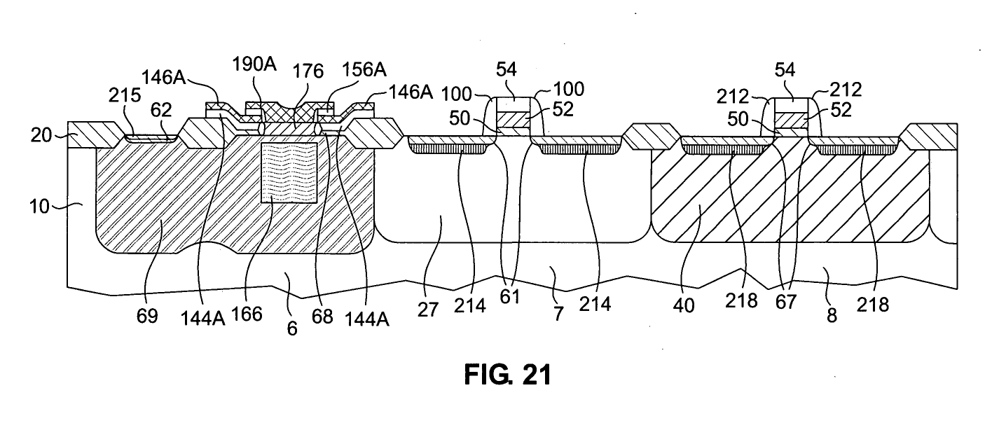

After removal of the base polysilicon photoresist mask 200 a photoresist layer (not illustrated) is patterned to form a n+ source/drain mask, e.g., to implant arsenic, forming source/drain regions 214 for the NMOSFET in the region 7. See FIG. 21. Note that the gate stack spacers 210 cause the source/drain regions 214 to be offset slightly from the previously implanted lightly doped regions 61. In portions of the source/drain regions 214 that extend below the lightly doped regions 61, the electric field formed between the source/drain regions 214 extends over a greater distance than the field between the lightly doped regions and thus is lower in magnitude than the field between the lightly doped regions. The lower electric field strength reduces “hot” electron effects and short channel effects.

Arsenic is also implanted into the bipolar collector region 143 through the same mask, forming an n+ ohmic collector contact region 215 with a relatively high dopant concentration to minimize contact resistance with a subsequently formed overlying collector contact.

A high dose of a p-type dopant is implanted through a patterned mask (not illustrated) into the n-tub 40 to form source/drain regions 218 for the PMOSFET in the region 8. The gate stack spacers 210 cause the source/drain regions 218 to be offset slightly from the previously implanted lightly doped regions 67. In portions of the source/drain regions 218 that extend below the lightly doped regions 67, the electric field formed between the source/drain regions 218 extends over a greater distance than the field between the lightly doped regions and thus is lower in magnitude than the field between the lightly doped regions. The lower electric field strength reduces “hot” electron effects and short channel effects.

FIG. 21 illustrates the final device appearance, prior to deposition of alternating dielectric layers and conductive layers for interconnecting the doped regions formed in the semiconductor layer 10.

Since the photoresist mask 200 is in place during formation of the gate stack spacers 210 and 212, no material is removed from the bipolar junction transistor layers within the bipolar junction transistor region 6 during the gate stack etch process. Thus the BiCMOS process according to the present invention avoids etching of the bipolar junction transistor layers and the attendant device degradation, as described above with respect to the embodiment presented in FIGS. 1-9.

While the present invention has been described with reference to preferred embodiments, it will be understood by those skilled in the art that various changes may be made and equivalent elements may be substituted for the elements thereof without departing from the scope of the invention. The scope of the present invention further includes any combination of elements from the various embodiments set forth herein. In addition, modifications may be made to adapt a particular situation to the teachings of the present invention without departing from its essential scope. Therefore, it is intended that the invention not be limited to the particular embodiments disclosed, but that the invention will include all embodiments falling within the scope of the appended claims.

What is claimed is:

1. A method for forming a bipolar junction transistor and a metal oxide semiconductor field effect transistor in a semiconductor layer, comprising:
providing the semiconductor layer;
forming MOSFET structures in a MOSFET region of the semiconductor layer;
depositing a spacer material layer over an upper surface of the semiconductor layer;
forming bipolar junction transistor structures, including an emitter material layer, in a bipolar junction transistor region of the semiconductor layer;
forming a patterned mask;
etching the emitter material layer using the mask to form an emitter;
etching the spacer material layer to form gate stack spacers in the MOSFET region prior to removing the mask; and
removing the mask.

2. The method of claim 1 wherein the step of forming MOSFET structures in the MOSFET region further comprises:
forming an isolation region;
forming a doped tub region;
forming a gate material layer stack; and
forming lightly doped regions.

3. The method of claim 1 wherein the step of depositing a spacer material layer further comprises depositing a silicon dioxide spacer material layer.

4. The method of claim 1 wherein the step of forming bipolar junction transistor structures comprises;
forming a bipolar junction transistor collector;
forming a bipolar junction transistor base; and
depositing an emitter polysilicon layer, wherein the emitter material layer comprises the emitter polysilicon layer.

5. The method of claim 1 further comprising forming additional MOSFET structures, including source/drain regions, in the MOSFET region after the step of removing the mask.

6. The method of claim 1 wherein the step of forming the patterned mask comprises forming a photoresist patterned mask.

7. The method of claim 1 wherein the step of forming the patterned mask comprises forming a hard mask patterned mask.

8. The method of claim 1 wherein the step of forming the patterned mask comprises:
forming a hard mask layer;
forming a photoresist layer,
patterning the photoresist layer; and
patterning the hard mask layer to form the patterned mask according to a pattern formed in the photoresist layer.

9. The method of claim 1 wherein the step of etching the spacer material layer comprises etching the material spacer layer using an etch chemistry comprising methyl fluoride, carbon tetrafluoride and argon.

10. The method of claim 9 wherein a ratio of the methyl fluoride, the carbon tetrafluoride and the argon is about 6:1:1.

11. The method of claim 9 wherein a flow rate of the methyl fluoride, the carbon tetrafluoride and the argon is about 72 sccm, 12 sccm and 10 sccm, respectively.

12. The method of claim 1 wherein during the step of etching the spacer material layer a temperature of the semiconductor layer is between about 30° C. and about 60° C.

13. The method of claim 1 wherein the step of removing the patterned mask comprises removing the patterned mask using oxygen in a microwave down stream plasma reactor.

14. A method for forming a bipolar junction transistor and a metal oxide semiconductor field effect transistor in a semiconductor layer, comprising:
providing the semiconductor layer;
forming MOSFET structures in a MOSFET region of the semiconductor layer;
depositing a spacer material layer over an upper surface of the semiconductor layer;
forming bipolar junction transistor structures, including a base material layer, in a bipolar junction transistor region of the semiconductor layer;
forming a patterned mask;
etching the base material layer using the mask to form a base;
etching the spacer material layer to form gate stack spacers in the MOSFET region prior to removing the patterned mask; and
removing the patterned mask.

15. The method of claim 14 wherein the step of depositing a spacer material layer further comprises depositing a silicon dioxide spacer material layer.

16. The method of claim 14 wherein the step of forming MOSFET structures in the MOSFET region further comprises:
forming an isolation region;
forming a doped tub region;
forming a gate material layer stack; and
forming lightly doped regions.

17. The method of claim 14 wherein the step of forming bipolar junction transistor structures comprises;
forming a bipolar junction transistor collector;
forming a bipolar junction transistor intrinsic base;
depositing a base polysilicon layer;
depositing an emitter polysilicon layer, wherein the base material layer comprises the base polysilicon layer; and
forming an emitter from the emitter polysilicon layer.

18. The method of claim 14 further comprising forming additional MOSFET structures, including source/drain regions, in the MOSFET region after the step of removing the patterned mask.

19. The method of claim 14 wherein the step of forming the patterned mask comprises forming a photoresist patterned mask.

20. The method of claim 14 wherein the step of forming the patterned mask comprises forming a hard mask patterned mask.

21. The method of claim 14 wherein the step of forming the patterned mask comprises:
forming a hard mask layer;
forming a photoresist layer,
patterning the photoresist layer; and
patterning the hard mask layer to form the patterned mask according to a pattern formed in the photoresist layer.

22. The method of claim 14 wherein the step of etching the spacer material layer comprises etching the material spacer layer using an etch chemistry comprising methyl fluoride, carbon tetrafluoride and argon.

23. The method of claim 22 wherein a ratio of the methyl fluoride, the carbon tetrafluoride and the argon is about 6:1:1.

24. The method of claim 22 wherein a flow rate of the methyl fluoride, the carbon tetrafluoride and the argon is about 72 sccm, 12 sccm and 10 sccm, respectively.

25. The method of claim 22 wherein during the step of etching the spacer material layer a temperature of the semiconductor layer is between about 30° C. and about 60° C.

26. The method of claim 14 wherein the step of removing the mask pattern comprises removing the mask pattern using oxygen in a microwave down stream plasma reactor.

27. Semiconductor structures comprising bipolar junction transistor structures and metal oxide semiconductor field effect transistor structures in a semiconductor layer, comprising:
a collector in a bipolar junction transistor region of the semiconductor layer;
a base in contact with the collector;
an emitter overlying an upper surface of the semiconductor layer;
a patterned mask overlying the emitter;
MOSFET structures, including a gate stack, in a MOSFET region of the semiconductor layer; and
a spacer material layer overlying the gate stack wherein the spacer material layer is etched to form gate stack spacers while the patterned mask overlies the emitter.

28. Semiconductor structures comprising bipolar junction transistor structures and metal oxide semiconductor field effect transistor structures in a semiconductor layer, comprising:
a collector in a bipolar junction transistor region of the semiconductor layer;
a base in contact with the collector;
an emitter overlying an upper surface of the semiconductor layer, the emitter in contact with the base and having a first thickness;
MOSFET structures, including a gate stack, in a MOSFET region of the semiconductor layer; and
a spacer material layer overlying the gate stack wherein the spacer material layer is etched to form gate stack spacers adjacent the gate stack, the emitter layer having the first thickness after the spacer material layer etch.
